(19) United States
(12) Patent Application Publication
(10) Pub. No.: US 2008/0017884 A1
(43) Pub. Date: Jan. 24, 2008

(54) DISPLAY SUBSTRATE, DISPLAY APPARATUS HAVING THE DISPLAY SUBSTRATE AND METHOD FOR MANUFACTURING THE DISPLAY APPARATUS

(76) Inventors: Chang-Oh Jeong, Suwon-si (KR); Sang-Gab Kim, Seoul (KR); Jun-Hyung Souk, Yongin-si (KR); Hong-Gyun Kim, Cheonan-si (KR); In-Sun Hwang, Suwon-si (KR); Min-Seok Oh, Yongin-si (KR); Hong-Kee Chin, Suwon-si (KR); Yu-Gwang Jeong, Yongin-si (KR); Seung-Ha Choi, Siheung-si (KR); Hi-Kuk Lee, Yongin-si (KR); Shi-Yul Kim, Yongin-si (KR)

Correspondence Address: F. CHAU & ASSOCIATES, LLC, 130 WOODBURY ROAD, WOODBURY, NY, 11797, US

(21) Appl. No.: 11/766,329

(22) Filed: Jun. 21, 2007

(30) Foreign Application Priority Data
Jul. 21, 2006 (KR) 10-2006-0068334

(51) Int. Cl. H01L 27/13; H01L 21/3205; H01L 23/48

(52) U.S. Cl. 257/203; 257/773; 438/587; 257/E23.016; 257/E21.535

(57) ABSTRACT

A display apparatus includes a first substrate, a gate line formed on the first substrate, a gate insulating layer formed on the gate line, a semiconductor layer formed on the gate insulating layer, a data line formed on the semiconductor layer and including a source electrode, a drain electrode facing the source electrode, a first electrode electrically connected to the drain electrode, in a second substrate facing the first substrate, a second electrode formed on the second substrate, and a liquid crystal layer disposed between the first electrode and the second electrode. At least one of the first and second electrodes includes a plurality of line patterns to polarize incident light.

### CROSS-REFERENCE TO RELATED APPLICATION

This application claims priority to Korean Patent Application No. 2006-68334, filed on Jul. 21, 2006 the disclosure of which is incorporated herein by reference in its entirety.

### BACKGROUND OF THE INVENTION

1. Technical Field

The present invention relates to a display substrate, a display apparatus having the display substrate and a method for manufacturing the display apparatus, and more particularly, to a display substrate capable of reducing manufacturing processes and costs thereof.

2. Discussion of the Related Art

A liquid crystal display (LCD) apparatus is more commonly used than a cathode ray tube (CRT) display apparatus, since a thickness of the LCD apparatus is thinner than the CRT display apparatus, and a weight of the LCD apparatus is lighter than the CRT display apparatus. However, since the LCD apparatus displays an image by using a liquid crystal layer as a light shutter, the LCD apparatus requires linearly polarized light to display an image.

Thus, polarizing plates are disposed over and under the LCD apparatus for linearly polarizing light emitted from a backlight assembly.

Since a price of the polarizing plate attached to the LCD apparatus is high manufacturing costs of the LCD apparatus increases. In addition, an additional process to attach the polarizing plate is necessary.

### SUMMARY OF THE INVENTION

Embodiments of the present invention provide a display substrate capable of reducing manufacturing processes and costs thereof, a display apparatus having the display substrate, and a method for manufacturing the display apparatus.

According to an exemplary embodiment of the present invention, the display substrate may include a base substrate, a gate line formed on the base substrate, a gate insulating layer formed on the base substrate to cover the gate line, a data line intersecting the gate line and including a source electrode, a drain electrode facing the source electrode, and an electrode electrically connected to the drain electrode. A plurality of line patterns are formed at the electrode to polarize incident light.

According to an exemplary embodiment of the present invention, the display apparatus may include a first substrate, a gate line formed on the first substrate, a gate insulating layer formed on the gate line, a semiconductor layer formed on the gate insulating layer, a data line formed on the semiconductor layer and including a source electrode, a drain electrode formed on the semiconductor layer and facing the source electrode, a first electrode electrically connected to the drain electrode, a second substrate facing the first substrate, a second electrode formed on the second substrate, and liquid crystal disposed between the first and second electrodes. At least one of the first and second electrodes may include a plurality of line patterns for polarizing incident light.

According to an exemplary embodiment of the present invention, the display apparatus may include a first substrate, a gate line formed on the first substrate, a gate insulating layer formed on the gate line, a data line intersecting the gate line to define a pixel area and including a source electrode, a drain electrode facing the source electrode, a first electrode that is formed in the pixel area and electrically connected to the drain electrode, and includes a plurality of line patterns for polarizing incident light, a passivation layer that covers a channel portion formed between the source and drain electrodes, a second substrate facing the first substrate, a second electrode formed on the second substrate, and liquid crystal disposed between the first and second electrodes. The passivation layer is exposed in the pixel area.

According to an exemplary embodiment of the present invention, a method for manufacturing a display apparatus may include forming a gate line on a first substrate, forming a gate insulating layer on the gate line, forming a data line and a drain electrode in which the data line intersects the gate line, forming a first electrode that is electrically connected to the drain electrode and includes a plurality of line patterns, and combining a second substrate with the first substrate such that the second substrate faces the first substrate. The data line includes a source electrode, and the drain electrode faces the source electrode.

According to embodiments of the present invention, a polarizing member is formed inside the display apparatus, so that a thickness and a weight of the display apparatus may be decreased and manufacturing costs of the display apparatus may be decreased.

### BRIEF DESCRIPTION OF THE DRAWINGS

Exemplary embodiments of the present invention can be understood in more detail from the following descriptions taken in conjunction with the accompanying drawings, in which;

FIG. 1 is a plan view illustrating a thin film transistor (TFT) display substrate according to an exemplary embodiment of the present invention;

FIG. 2 is a plan view illustrating a common electrode display substrate according to an exemplary embodiment of the present invention;

FIG. 3 is a cross-sectional view illustrating a display apparatus including the TFT display substrate shown in FIG. 1 and the common electrode display substrate shown in FIG. 2, which is taken along the line I-I′ in FIG. 1.

FIG. 4 is a plan view illustrating a TFT display substrate according to an exemplary embodiment of the present invention;

FIG. 5 is a plan view illustrating a common electrode display substrate according to an exemplary embodiment of the present invention;

FIG. 6 is a plan view illustrating a display apparatus including the TFT display substrate shown in FIG. 4 and the common electrode display substrate shown in FIG. 5;

FIG. 7 is a cross-sectional view taken along the line II-II′ of the display apparatus shown in FIG. 6;

FIG. 8 is a plan view illustrating a TFT display substrate according to an exemplary embodiment of the present invention;

FIG. 9 is a cross-sectional view taken along the line III-III′ in FIG. 8; and

FIGS. 10 to 15 are cross-sectional views illustrating a method for manufacturing a TFT display substrate according to an exemplary embodiment of in the present invention.

### DESCRIPTION OF EXEMPLARY EMBODIMENTS

The invention is described more fully hereinafter with reference to the accompanying drawings, in which embodiments of the invention are shown. This invention may, however, be embodied in many different forms and should not be construed as limited to the embodiments set forth herein.

It will be understood that when an element or layer is referred to as being “on,” “connected to” or “coupled to” another element or layer, it can be directly on, connected or coupled to the other element or layer or intervening elements or layers may be present.

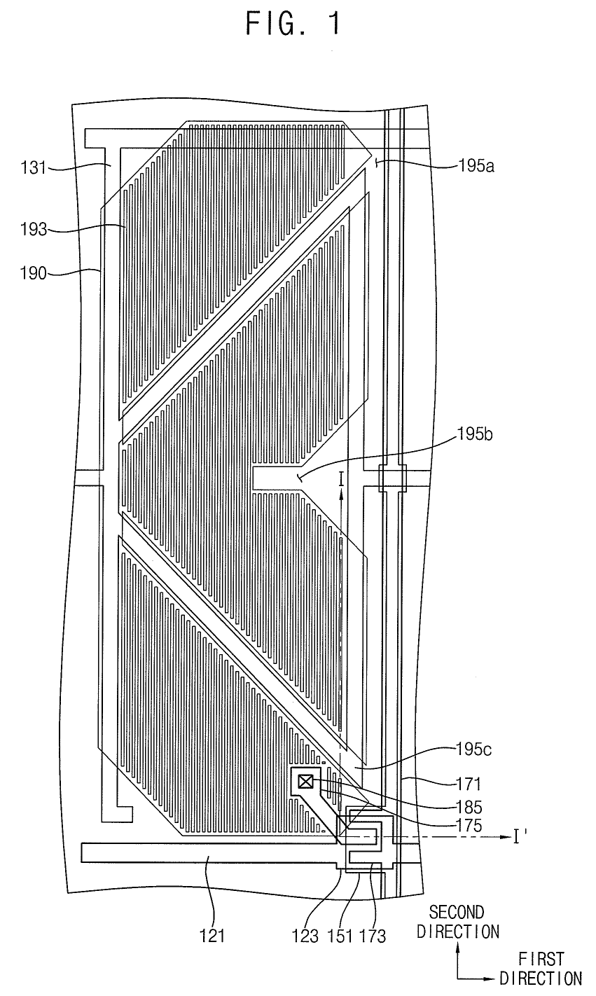

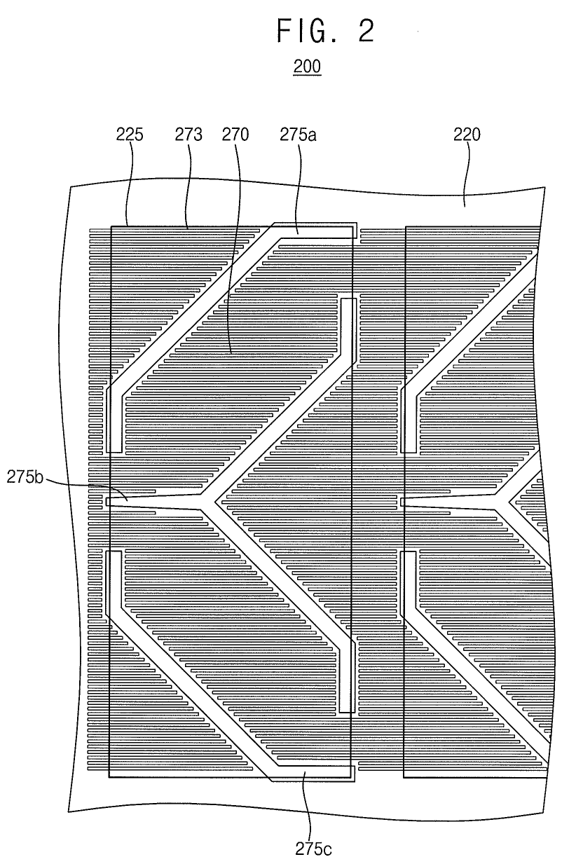

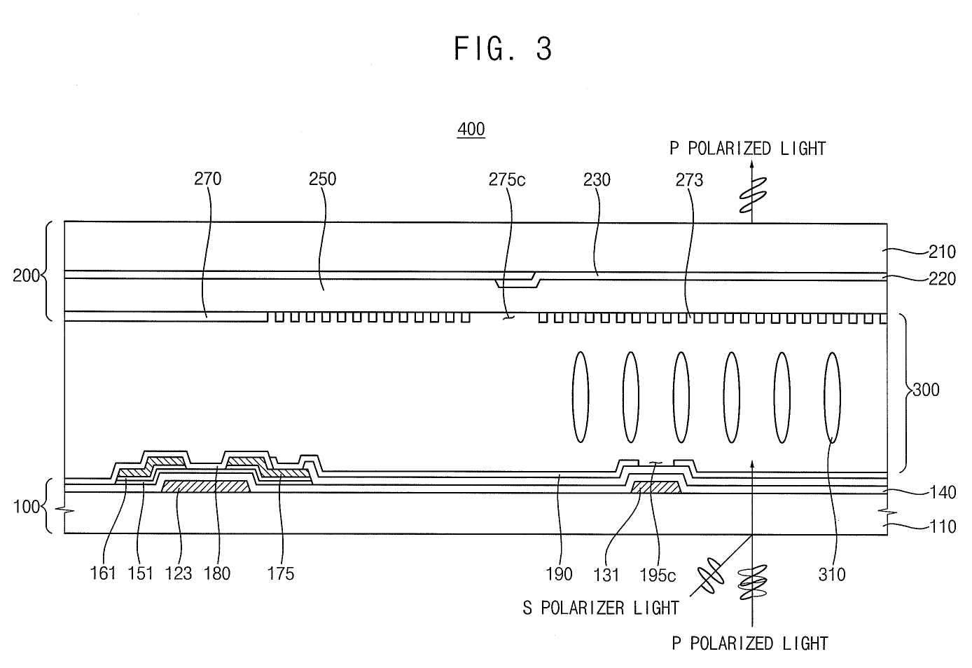

FIG. 1 is a plan view illustrating a thin film transistor (TFT) display substrate according to an exemplary embodiment of the present invention. FIG. 2 is a plan view illustrating a common electrode display substrate according to an exemplary embodiment of the present invention. FIG. 3 is a cross-sectional view illustrating a display apparatus including the TFT display substrate shown in FIG. 1 and the common electrode display substrate shown in FIG. 2, which is taken along the line I-I′ in FIG. 1.

Referring to FIGS. 1 to 3, a display apparatus 400 according to an exemplary embodiment of the present invention includes a TFT display substrate 100, a common electrode display substrate 200 and a liquid crystal layer 300.

A plurality of gate lines 121 are formed on an insulating substrate 110. The insulating substrate 110 may include a material such as a transparent glass or a plastic material. A maintenance electrode line 131 is formed from the same layer as the gate lines 121. The maintenance electrode line 131 may have various shapes and arrangements.

The gate lines 121 transfer a gate signal, and extend along a first direction. The gate lines 121 include a plurality of gate electrodes 123 protruded along a second direction crossing the first direction.

The gate lines 121 may include, for example, an aluminum-based material such as aluminum (Al) or an aluminum alloy, a silver-based material such as silver (Ag) or a silver alloy, a copper-based material such as copper (Cu) or a copper alloy, a molybdenum-based material such as molybdenum (Mo) or a molybdenum alloy, chromium (Cr), tantalum (Ta), titanium (Ti). The gate lines 121 may include a multi-layered structure that includes two conductive layers (not shown) having different physical characteristics. A first conductive layer may include a metal having a low resistivity to decrease a signal delay or a voltage drop. A second conductive layer may include a metal having good physical, chemical and electrical contact characteristics with a material such as indium tin oxide (ITO) or indium zinc oxide (IZO). For example, the first conductive layer may include chromium (Cr) or a chromium alloy, and the second conductive layer may include aluminum or an aluminum alloy. Alternatively, the first conductive layer may include aluminum or an aluminum alloy and the second conductive layer may include molybdenum or a molybdenum alloy. However, the gate lines 121 may include various metals or conductive materials.

A gate insulating layer 140 is formed on the gate line 121. The gate 1i insulating layer 140 may include, for example, a silicon nitride (SiNx) and/or a silicon oxide (SiOx).

A semiconductor layer 151 is formed on the gate insulating layer 140. The semiconductor layer 151 may include hydrogenated amorphous silicon (a-Si) and/or poly-silicon. In an embodiment, the semiconductor layer 151 overlaps the gate electrode 123 and is formed to have a line-shape along a lower portion of the data line. Alternatively, the semiconductor layer 151 may overlap the gate electrode 123 and may be formed to have an island-shape.

An ohmic contact element 161 is formed on the semiconductor layer 151. The ohmic contact element 161 may include a material such as n+ hydrogenated a-Si doped with N-type dopants, e.g., phosphorus (P) at a high concentration or silicide.

A plurality of data lines 171 and a plurality of drain electrodes 175 are formed on the ohmic contact element 161 and gate insulating layer 140.

The data lines 171 transfer the data signals, and extend along a second direction. The data lines 171 include a plurality of source electrodes extended toward the gate electrodes 123.

Drain electrodes 175 are separated from the data lines 171, and a drain electrode 175 faces a source electrode 173 with a gate electrode 123 disposed therebetween. Each drain electrode 175 includes a first end portion having a wide board shape and a second end portion having a bar shape. The second end portion can be partially surrounded by the source electrode 173.

A TFT includes the gate electrode 123, the source electrode 173, the in drain electrode 175 and the semiconductor layer 151. A channel of the TFT is formed between the source electrode 173 and the drain electrode 175.

The data line 171 and the drain electrode 175 may include a refractory metal such as molybdenum (Mo), chromium (Cr), tantalum (Ta), titanium (Ti), or an alloy thereof. The data line 171 and the drain electrode 175 may have the multi-layered structure. For example, the multi-layered structure may have a double-layered structure that has a tower layer of chromium, molybdenum or an alloy thereof and an upper layer of aluminum or an aluminum alloy, and a triple-layered structure that has a lower layer of molybdenum or a molybdenum alloy, a middle layer of aluminum or an aluminum alloy and an upper layer of molybdenum or a molybdenum alloy. The data line 171 and the drain electrode 175 may include various metals or conductive materials.

A passivation layer 180 is formed on the data line 171, the drain electrode 175 and an exposed semiconductor layer 151. The passivation layer 180 may include, for example, an inorganic insulating material or an organic insulating material and may be formed to have a flat surface. The inorganic insulating material may include, for example, silicon nitride (SiNx) and/or silicon oxide (SiOx). The organic insulating material may have photosensitivity, and a dielectric constant of the organic insulating material may be under about 4.0. The passivation layer 180 may have a double-layered structure having upper and lower inorganic insulating layers.

A plurality of pixel electrodes 190 are formed on the passivation layer 180. According to an exemplary embodiment of the present invention, a plurality of in line patterns 193 are formed at the pixel electrode 190 to polarizer incident light. The line pattern 193 may be defined as an opening portion (or slit) having a line shape in the pixel electrode 190.

Referring to FIG. 3, the pixel electrode 190 in which a small line pattern 193 formed polarizes light incident through the substrate 100. FIG. 3 illustrates the light vertically incident through the substrate 100, but the light may enter the substrate 100 at a diagonal angle.

An s-polarized light is defined as light having an electric field vector, which is in parallel with an extended direction of the line pattern 193. A p-polarized light is defined as light having the electric field vector, which is perpendicular to the extended direction of the line pattern 193. When the incident light passes through the plurality of line patterns 193, the s-polarized light that is parallel with the extended direction of the line pattern 193 is reflected, and the p-polarized light that is perpendicular to the extended direction of the line pattern 193 is transmitted. Thus, the line pattern 193 may be used as a polarizing plate, and an axis that is perpendicular to the extended direction of the line pattern 193 is a transmissive axis.

A polarizing capacity depends on a width of line pattern 193 and a distance between the line patterns 193. When a wavelength of the incident light is greater than the width of the line pattern 193, the p-polarized light that is perpendicular to the line pattern 193 may pass through the line pattern 193. Since the wavelength of a visible ray is between about 380 nm and about 700 nm, the width of the line pattern 193 may be substantially equal to or less than about 200 nm.

In an exemplary embodiment of the present invention, the plurality of line patterns 193 is formed substantially parallel with the data line 171. The width of the line pattern 193 is substantially equal to or less than about 100 nm. In an embodiment, the width of line pattern can be about 70 nm. In addition, the distance between the line patterns 193 is substantially equal to or less than about 200 nm. In an embodiment, the distance between the line patterns 193 can be about 70 nm. A thickness of the pixel electrode 190 having the line pattern 193 may be in a range of from about 10 nm to about 500 nm. In an embodiment, the pixel electrode can be about 150 nm thick.

The pixel electrode 190 may include an upper opening pattern 195a, a middle opening pattern 195b and a lower opening pattern 195c. The pixel electrode 190 is divided into a plurality of areas by the opening patterns 195a, 195b and 195c.

When a voltage is applied a longitudinal arrangement direction of most liquid crystal molecules is perpendicular to a direction of the upper opening pattern 195a or the lower opening pattern 195c. The upper opening pattern 195a or the lower opening pattern 195c that determines the longitudinal arrangement direction of most liquid crystal molecules, i.e., a direction of liquid crystal domain, is defined as an opening pattern direction.

The upper opening pattern 195a and the lower opening pattern 195c may be slant with respect to the gate line 121 by about 30° to about 60° (hereinafter an angle means an acute angle between two lines intersecting each other). In an embodiment, the upper opening pattern 195a and the lower opening pattern 195c may be slant with respect to the gate line 121 by about 45°. The middle opening pattern 195b is formed between the upper and lower opening patterns 195a and 195c. The plurality of opening patterns 195a, 195b and 195c may be formed to have a width of about 5 μm to about 50 μm.

The line pattern 193 is formed in an area of the pixel electrode 190 in which the opening patterns 195a, 195b and 195c of the pixel electrode 190 are not formed. In other words, the line pattern 193 is formed in the plurality of areas divided by the opening patterns 195a, 195b and 195c.

In an exemplary embodiment of the present invention, the extended direction of the line pattern 193 may be slant with respect to the direction of the opening pattern in the pixel electrode 190 by about 30° to about 60°. In an embodiment, the extended direction of the line pattern 193 may be slant with respect to the direction of the opening pattern in the pixel electrode 190 by about 45°. The longitudinal arrangement direction of the liquid crystal molecules due to the electric field generated by the opening pattern 195a in the pixel electrode 190 is slant with respect to the polarized direction of the light polarized by the line pattern 193 in the pixel electrode 190 by 45°, so that brightness may be maximized in a white mode.

The pixel electrode 190 is electrically connected to the drain electrode 175 through a contact hole 185. The pixel electrode 190 receives a data voltage from the drain electrode 175. The electric field is generated between the pixel electrode 190 receiving the data voltage and the common electrode 270 of the common electrode display substrate 200 receiving a common voltage, so that the longitudinal arrangement direction of the liquid crystal molecules 310 is determined.

The pixel electrode 190 may include a conductive material. The conductive material may include, for example, aluminum (Al), silver (Ag), copper (Cu), molybdenum (Mo), chromium (Cr), tantalum (Ta), titanium (Ti) or an alloy thereof. The pixel electrode 190 may include, for example, a single metallic layer or a multi-metallic layer.

An alignment layer (not shown) is formed on the pixel electrode 190. The alignment layer may include an organic alignment layer including polyimide and an inorganic alignment layer including, for example, silicon oxide (SiOx) or silicon carbide (SiCx). In an embodiment, the alignment layer may include a vertical alignment layer arranging the liquid crystal molecules substantially perpendicular to the substrate.

Referring the FIGS. 2 and 3, a light blocking member 220 is formed on an Insulating substrate 210 that includes, for example, transparent glass or plastic. The light blocking member 220 that is called a black matrix prevents light from being leaked between the pixel electrodes 190. The light blocking member 220 faces the pixel electrode 190, and includes a plurality of opening portions 225 that have a shape substantially the same as that of the pixel electrode 190. The light blocking member 220 may include a portion corresponding to the gate line 121 and the data line 171, and a portion corresponding to the TFT.

A plurality of color filters 230 are formed on the substrate 230. The color filters 230 may be disposed in an area enclosed by the light blocking member 220, and may longitudinally extend along a row of the pixel electrode 190. Each color filter 230 may display one of primary colors including red, green and blue colors.

An overcoat layer 250 is formed on the color filter 230 and the light blocking member 220. The overcoat layer 250 may include an (organic) insulating material to prevent the color filter 230 from being exposed. A surface of the overcoat layer 250 may be flat. The overcoat layer 250 is optional.

The common electrode 270 is formed on the overcoat layer 250. When the common voltage is applied to the common electrode 270 and the data voltage is applied to the pixel electrode 190, the electric field is generated on a surface of the display substrates 100 and 200 due to a voltage difference between two substrates 100 and 200. In response to the electric field, the longitudinal arrangement direction of liquid crystal molecules is changed perpendicular to a direction of the electric field, so that an amount of light may be controlled.

According to an exemplary embodiment of the present invention, a plurality of line patterns 273 are formed in the common electrode 270. An extended direction of the line pattern 273 formed in the common electrode 270 is substantially perpendicular to the extended direction of the line pattern 193 formed in the pixel electrode 190. Alternatively, the extended direction of the line pattern 273 formed in the common electrode 270 may be substantially parallel with the extended direction of the line pattern 193 formed in the pixel electrode 190.

The width of the line pattern 273 may be equal to or less than about 100 nm. In an embodiment, the width of the line pattern 273 may be about 70 nm. The distance between the line patterns 273 may be equal to or less than about 200 nm. In an embodiment, the distance between the line patterns 273 may be about 70 nm. In addition, the thickness of the common electrode 270 may be in a range of from about 10 nm to about 500 nm. In an embodiment, the thickness of the common electrode 270 may be about 150 nm.

The common electrode 270 may include an upper opening pattern 275a, a middle opening pattern 275b and a lower opening pattern 275c. The common electrode 270 is divided into a plurality of areas by the opening patterns 275a, 275b and 275c. Each of the opening patterns 275a, 275b and 275c intersects the opening patterns 195a, 195b and 195c of the pixel electrode 190, respectively. The upper opening pattern 275a includes a line that is slant with respect to the gate line 121 by about 45° and substantially parallel with the gate line 121. The lower opening pattern 275c includes the line that is slant with respect to the gate line 121 by about 45° and parallel with the gate line 121. The middle opening pattern 275b includes the line that is slant with respect to the gate line 121 by about 45° and parallel with the gate line 121.

Directions of the upper opening pattern 195a and the lower opening pattern 195c that determine the longitudinal arrangement direction of most liquid crystal molecules are defined as opening pattern directions.

The opening pattern may include various numbers and shapes due to in design parameters.

The common electrode 270 is divided into the plurality of areas by the opening patterns 275a, 275b and 275c.

However, the line pattern 273 is formed in an area where the opening patterns 275a, 275b and 275c of the common electrode 270 are not formed. For example, the line pattern 273 is formed in the plurality of areas divided by the opening patterns 275a, 275b and 275c. In an embodiment, the extended direction of the line pattern 273 is slanted with respect to the opening pattern direction of the common electrode by an angle of about 30° to about 60°. The extended direction of the line pattern 273 may be slanted with respect to the opening pattern direction of the common electrode by about 45°. In an embodiment, the longitudinal arrangement direction of liquid crystal molecules due to the electric field that is generated by the opening patterns 275a, 275b and 275c of the common electrode 270 is slant with respect to the polarizing direction of the light polarized by the line pattern 273 of the common electrode 270 by about 45°, so that the brightness may be maximized in the white mode.

The common electrode 270 may include a conductive material. The conductive material may include, for example, aluminum (Al), silver (Ag), copper (Cu), molybdenum (Mo), chromium (Cr), tantalum (Ta), titanium (Ti) or an alloy thereof. The common electrode 270 may include, for example, a single metallic layer or a multi-metallic layer.

An alignment layer is formed on the common electrode 270. The alignment layer may include, for example, an organic alignment layer including polyimide and/or an inorganic alignment layer including silicon oxide (SiOx) and/or silicon carbide (SiCx). In an embodiment, the alignment layer may include a vertical alignment layer.

The LCD apparatus may include the TFT display substrate 100, the common electrode display substrate 200 and the liquid crystal layer 300.

In an exemplary embodiment of the present invention, the longitudinal arrangement direction of liquid crystal molecules 310 of the liquid crystal layer 300 is arranged perpendicular to the substrates 110 and 210, when the electric field is not generated. In an embodiment, light that is polarized through the pixel electrode 190 of the TFT display substrate 100 passes through the liquid crystal layer 300 to maintain the characteristics of the light. A transmitting axis of the common electrode 270 is perpendicular to the transmitting axis of the pixel electrode 190, so that the light is blocked and darkness is displayed.

However, the line pattern 193 of the pixel electrode 190 may be substantially parallel with the line pattern 273 of the common electrode 270. In an embodiment, when the electric field is not generated, the light passed the pixel electrode 190 passes again through the common electrode 270, so that brightness is displayed.

The LCD apparatus including the line pattern formed in both pixel and common electrodes is explained above. Alternatively, the line pattern may be formed in one of the pixel and common electrodes. For example, the line pattern may be formed in the pixel electrode, and the common electrode display substrate may include an additional polarizing plate. Alternatively, the line pattern may be formed in the common electrode, and the TFT display substrate may include the additional polarizing plate.

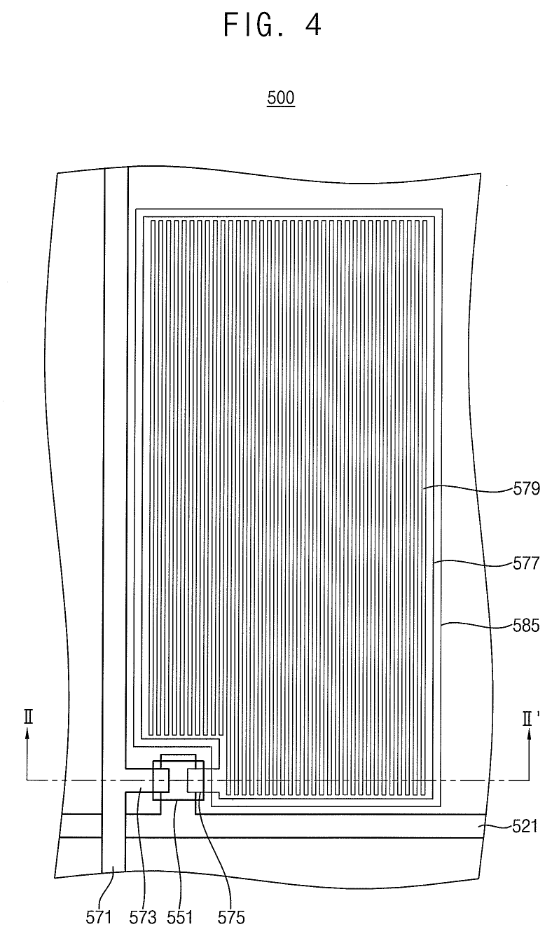

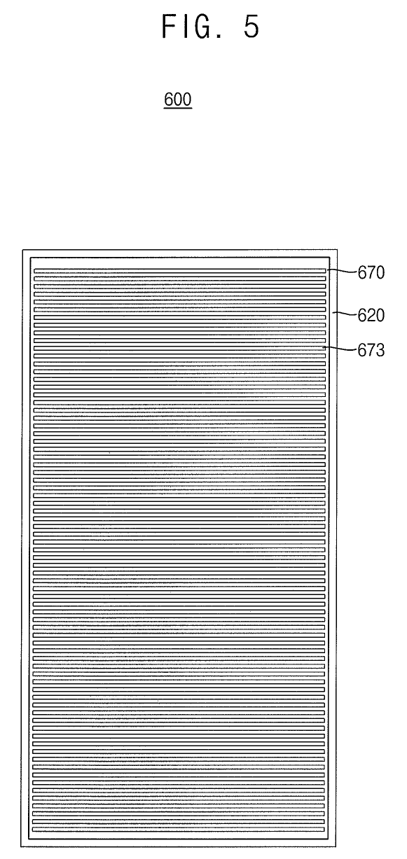

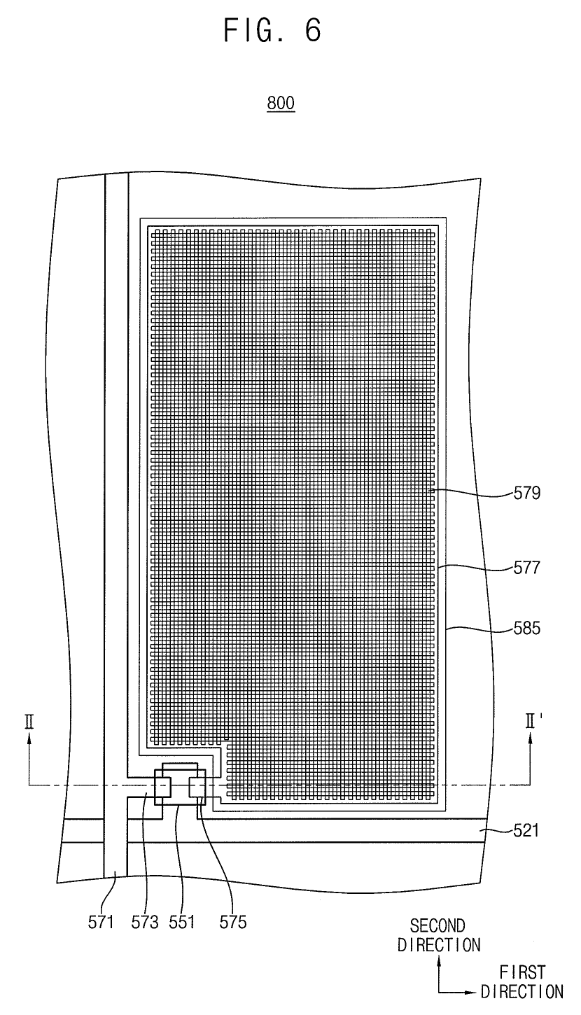

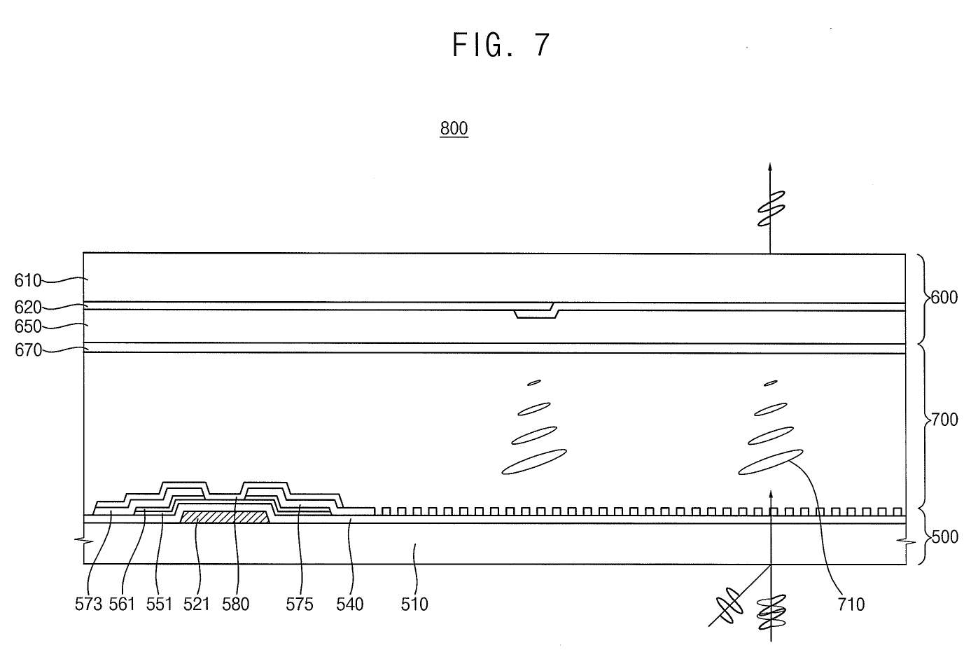

FIG. 4 is a plan view illustrating a TFT display substrate according to an exemplary embodiment of the present invention. FIG. 5 is a plan view illustrating a common electrode display substrate according to an exemplary embodiment of the present invention. FIG. 6 is a plan view illustrating a display apparatus including the TFT display substrate shown in FIG. 4 and the common electrode display substrate shown in FIG. 5. FIG. 7 is a cross-sectional view taken along the line II-II′ of the display apparatus in FIG. 6.

Referring to FIGS. 4, 6 and 7, a TFT display substrate 500 may include an insulating substrate 510, a gate line 521, a gate insulating layer 540, a semiconductor layer 551, an ohmic contact element 561, a data line 571, a pixel electrode 577 and a passivation layer 580.

The pixel electrode 577 is formed from the same layer as the data line 571. The pixel electrode 577 may include the same materials as that of the data line 571 and the drain electrode 575. The pixel electrode 577, the data line 571 and the drain electrode 575 may be formed from the same layer through the same process. Alternatively, the pixel electrode 577, the data line 571 and the drain electrode 575 may be formed respectively when the thicknesses of the pixel electrode 577, the data line 571 and the drain electrode 575 are different from one another. The pixel electrode 577 is physically connected to the drain electrode 575 and receives a data voltage from the drain electrode 575.

The pixel electrode 577 may include the conductive material. The conductive material may include, for example, aluminum (Al), silver (Ag), copper (Cu), molybdenum (Mo), chromium (Cr), tantalum (Ta), titanium (Ti) or an alloy thereof. The pixel electrode 577 may include, for example, the single metallic layer or the multi-metallic layer.

The pixel electrode 577 may include a plurality of line patterns 579 to polarize incident light. The plurality of line patterns 579 is substantially parallel with the data line 571. In an embodiment, the width of line pattern 579 is about 70 nm, the distance between the line patterns 579 is about 70 nm, and the thickness of the pixel electrode 577 in which the line pattern 579 is formed is about 150 nm.

The passivation layer 580 is formed to cover a channel portion after the data line 571 is formed. The passivation layer 580 includes an opening portion 585 in an area where the pixel electrode 577 is formed. The passivation layer 580 may include an organic insulating material or an inorganic insulating material. The passivation layer 580 may have a flat surface. The inorganic insulating material may include, for example, silicon nitride (SiNx) and/or silicon oxide (SiOx). The organic insulating material may have photosensitivity, and the dielectric constant of the organic insulating material may be no higher than about 4.0. In addition, the passivation layer 580 may have a double layer having a lower inorganic insulating layer and an upper inorganic insulating layer to improve insulating characteristics of an organic insulating layer and to prevent the exposed semiconductor layer from being damaged.

After the passivation layer 580 is formed, an alignment layer (not shown) is formed on the entire substrate. Since the passivation layer 580 includes the opening portion 585, the alignment layer is formed on the pixel electrode 577.

Referring to FIGS. 5, 6 and 7, the common electrode display substrate 600 may include an insulating substrate 610, a light blocking member 620, a color filter 630, an overcoat layer 650 and a common electrode 670.

The common electrode display substrate 600 may include the common electrode 670 in which a plurality of line patterns 673 are formed to polarize incident light. In an embodiment, the plurality of line patterns 673 is formed in the common electrode to polarize the incident light, and is substantially perpendicular to the line pattern 579 formed in the pixel electrode 577. However, the line pattern 673 formed in the common electrode 670 may be formed substantially parallel with the line pattern 579 formed in the pixel electrode 577.

In an embodiment, the width of the line pattern 673 is about 70 nm, the distance between the line patterns 673 is about 70 nm, and the thickness of the common electrode 670 is about 150 nm. An alignment layer is formed on the common electrode 670.

The LCD apparatus 800 may include a TFT display substrate 500, a common electrode display substrate 600 and a liquid crystal layer 700.

When an electric field is not generated, the longitudinal arrangement direction of the liquid crystal molecules 710 of the liquid crystal layer 700 is substantially parallel with a surface adjacent to the TFT display substrate 500 in and the common electrode display substrate 600, and is twisted from the TFT display substrate 500 to the common electrode display substrate 600.

To perform the above, the alignment layer (not shown) formed on the TFT display substrate 500 may be rubbed along the first direction substantially parallel with the gate line 521, the alignment layer (not shown) formed on the common electrode display substrate 600 may be rubbed along a second direction substantially perpendicular to the first direction. The transmitting axis of the pixel electrode 577 is substantially parallel with the first direction, and the transmitting axis of the common electrode 670 is substantially parallel with the second direction. However, the transmitting axis of the pixel electrode 577 is substantially perpendicular to the first direction, and the transmitting axis of the common electrode 670 is substantially perpendicular to the second direction.

The polarized light that has passed through the pixel electrode 577 of the TFT display substrate 500 passes through the liquid crystal layer 700, so that a phase retardation occurs due to an anisotropic refractive index of the liquid crystal molecules. In an embodiment, when the voltage is not applied, the polarizing direction of the light may be rotated by about 90° by controlling the distance between the display substrates 500 and 600. Since the transmitting axis formed in the pixel electrode 577 and the transmitting axis formed in the common electrode 670 are perpendicular to each other, the polarized light passes through, thereby brightening thereof.

However, the line pattern 579 of the pixel electrode 577 may be formed substantially parallel with the line pattern of the common electrode 670. In an embodiment, the light passing through the pixel electrode 577 is blocked by the common electrode 670, thereby darkening thereof.

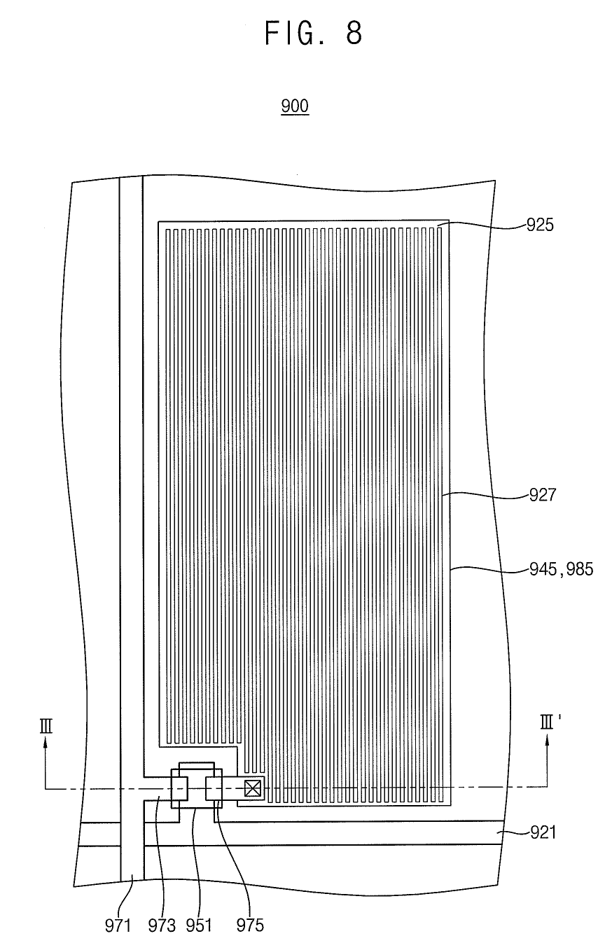

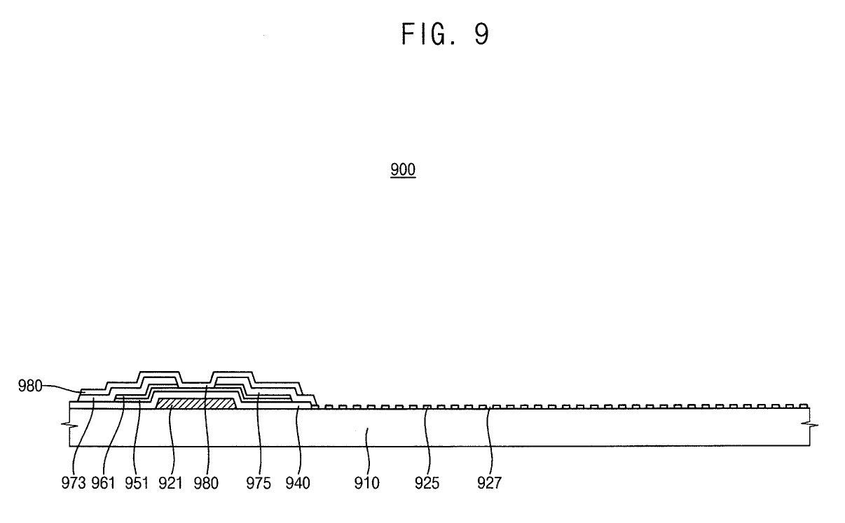

FIG. 8 is a plan view illustrating a TFT display substrate according to an exemplary embodiment of the present invention. FIG. 9 is a cross-sectional view taken along the line III-III′ in FIG. 8.

Referring to FIGS. 8 and 9, the TFT display substrate 900 may include an insulating substrate 910, a gate line 921, a pixel electrode 925, a gate insulating layer 940, a semiconductor layer 951, an ohmic contact element 961, a data line 971 including a source electrode 973, and a passivation layer 980.

The TFT display substrate 900 may include the pixel electrode 925 that is formed from the same layer as the gate line 921. The pixel electrode 925 includes a plurality of line patterns 927 to polarize the incident light. In addition, the pixel electrode 925 is electrically connected to the drain electrode 975 and receives the data voltage from the drain electrode 975.

The pixel electrode 925 may include a conductive material. The conductive material may include, for example, aluminum (Al), silver (Ag), copper (Cu), molybdenum (Mo), chromium (Cr), tantalum (Ta), titanium (Ti) or an alloy thereof. The pixel electrode 925 may include, for example, a single metallic layer or a multi-metallic layer. In addition, the pixel electrode 925 and the gate line 921 may be formed from the same layer through the same process, and the pixel electrode 925 may be formed with the same material as the gate line 921.

In an embodiment, the plurality of line patterns 927 is formed parallel with the data line 971. The width of the line pattern 927 is about 70 nm, the distance between the line patterns 927 is about 70 nm, and the thickness of the pixel electrode 925 in which the line pattern 927 is formed is about 150 nm.

The gate insulating layer 940 is formed on the gate line 921. The gate insulating layer 940 has an opening portion 945 that is formed in the pixel electrode 925. The semiconductor layer 951 and the ohmic contact element 961 are formed on the gate insulating layer 940. The data line 971 intersects the gate line 921. The source electrode 973 electrically connected to the data line 971 and the drain electrode 975 facing the source electrode 973 are formed on the semiconductor layer 951.

The passivation layer 980 includes an opening portion 985 that is formed in the pixel electrode 925. The opening portion 985 of the passivation layer 980 corresponds to the opening portion 945 of the gate insulating layer 940.

In an embodiment, the TFT display substrate eliminates the passivation layer or the gate insulating layer formed on the pixel electrode to prevent afterimage. Thus, the electric field to drive the liquid crystal between the pixel electrode and the common electrode is effectively formed.

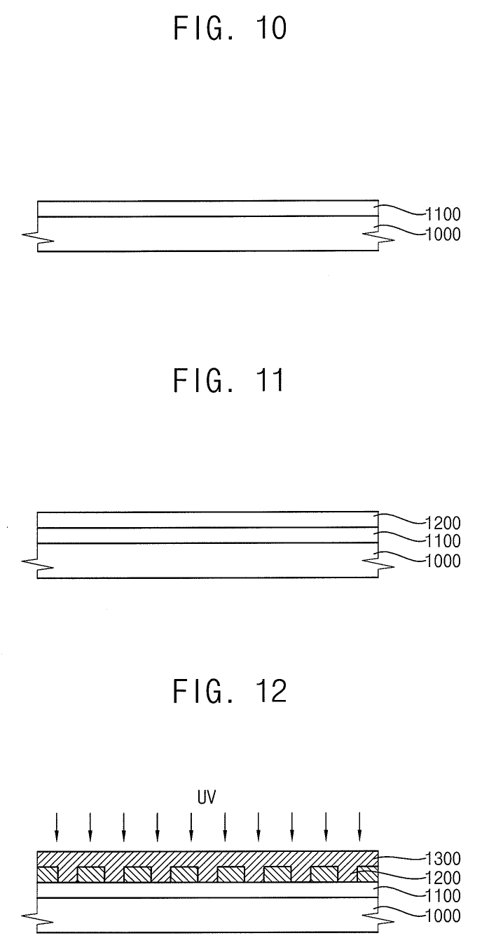

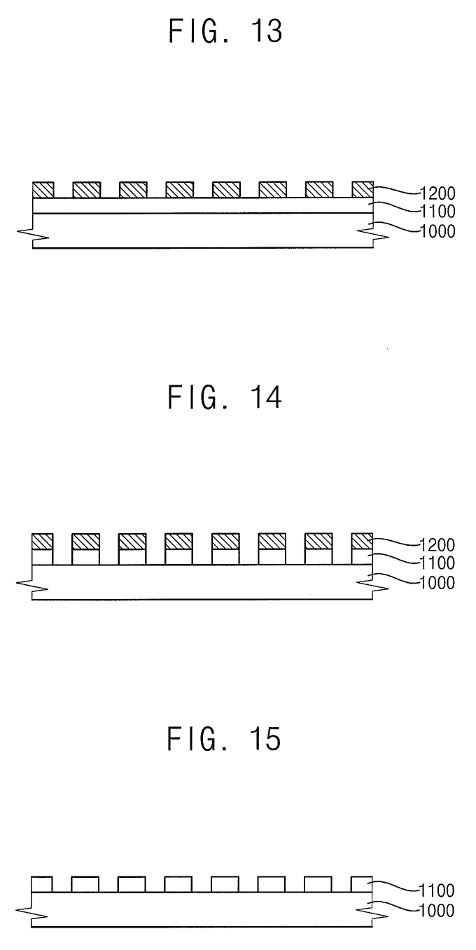

FIGS. 10 to 15 are cross-sectional views illustrating a method for manufacturing a TFT display substrate according to an exemplary embodiment of the present invention.

The method for manufacturing the TFT display substrate includes forming a gate line extending along the first direction on the insulating substrate, forming a gate insulating layer on the insulating substrate having the gate line formed thereon, forming a semiconductor layer on the gate insulating layer corresponding to the gate electrode extended from the gate line, forming a data line, a source electrode and a drain electrode extending along the second direction crossing the first direction on the insulating substrate having the semiconductor layer formed thereon, forming a passivation layer covering the data line, the source electrode and the drain electrode, forming a pixel electrode electrically connected to the drain electrode on the passivation layer corresponding to the pixel area, and forming a plurality of line patterns on the pixel electrode.

Referring to FIGS. 10 to 14, a metallic layer 1100 is coated on the substrate 1000 in which the passivation layer is formed. For example, aluminum may be sputtered to form the metallic layer 1100 on the entire substrate 1000.

An organic material 1200 is coated on the metallic layer 1100 by an ink jetting or a spin coating method. Then, a mold 1300 having a pattern is disposed on the substrate and is compressed, so that the pattern is formed on the organic material 1200. The organic material 1200 is cured by ultraviolet (UV) light. An embossed pattern formed on the mold 1300 corresponds to the plurality of line patterns and an opening pattern formed in the pixel electrode.

The mold 1300 is eliminated, and the organic material 1200 having the pattern and the metallic layer 1100 are etched. For example, the pattern may be formed by a dry etching. Then, the organic material 1200 is eliminated by an ashing process, and only a patterned metallic layer 1100 may remain.

The organic material pattern corresponding to the opening pattern formed between the pixel electrodes is formed through exposing and developing processes using a mask. The organic material pattern corresponding to the plurality of line patterns is formed through a laser interference lithography process.

When the gate line and the pixel electrode are formed from the same layer, and when the data line and the pixel electrode are formed from the same layer, the method mentioned above may be applicable. In addition, the line pattern to polarize the incident light after forming the common electrode on the common electrode display substrate may be formed through the above method.

According to embodiments of the present invention, the electrode of the display apparatus may be used for the polarizing plate, so that the polarizing plate disposed at a rear of the display apparatus may be eliminated and the method for manufacturing the display apparatus may be simplified.

In addition, since an additional layer is not disposed on the electrode of the display apparatus, the electric field to drive the liquid crystal molecules may be effectively generated.

Although the illustrative embodiments of the present invention have been described herein with reference to the accompanying drawings, it is to be understood that the present invention should not be limited to those precise embodiments and that various other changes and modifications may be affected therein by one of ordinary skill in the related art without departing from the scope or spirit of the invention. All such changes and modifications are intended to be included within the scope of the invention as defined by the appended claims.

What is claimed is:

1. A display substrate comprising:
a base substrate;
a gate line formed on the base substrate;
a gate insulating layer formed on the base substrate;
a data line intersecting the gate line and including a source electrode;
a drain electrode facing the source electrode; and
an electrode electrically connected to the drain electrode, the electrode including a plurality of line patterns to polarize incident light.

2. The display substrate of claim 1, wherein a distance between adjacent line patterns is substantially equal to or less than about 200 nm.

3. The display substrate of claim 2, further comprising an alignment layer formed on the electrode,

4. The display substrate of claim 1, wherein a width of each line pattern is substantially equal to or less than about 100 nm.

5. The display substrate of claim 1, wherein the electrode comprises at least one selected from the group consisting of aluminum (Al), silver (Ag), copper (Cu), molybdenum (Mo), chromium (Cr), tantalum (Ta), titanium (Ti) and an alloy thereof.

6. A display apparatus comprising:
a first substrate;
a gate Sine formed on the first substrate,
a gate insulating layer formed on the gate line,
a semiconductor layer formed on the gate insulating layer,
a data line formed on the semiconductor layer and including a source electrode;
in a drain electrode formed on the semiconductor layer and facing the source electrode;
a first electrode electrically connected to the drain electrode;
a second substrate facing the first substrate;
a second electrode formed on the second substrate, and
a liquid crystal layer disposed between the first electrode and the second electrode,
wherein at least one of the first and second electrodes includes a plurality of line patterns to polarize incident light.

7. The display apparatus of claim 6, wherein the first electrode comprises the plurality of line patterns, and the second substrate comprises a polarizing plate.

8. The display apparatus of claim 6, wherein the second electrode comprises the plurality of line patterns, and the first substrate comprises a polarizing plate.

9. The display apparatus of claim 6, wherein the plurality of line patterns comprises a plurality of first line patterns formed at the first electrode and extended along a first direction, and a plurality of second line patterns formed at the second electrodes and extended along a second direction substantially perpendicular to the first direction.

10. The display apparatus of claim 6, wherein a distance between adjacent line patterns is substantially equal to or less than about 200 nm.

11. The display apparatus of claim 10, further comprising:
a first alignment layer formed on the first electrode; and
a second alignment layer formed on the second electrode.

12. The display apparatus of claim 6, wherein at least one of the first and second electrodes has an opening pattern to change a direction of an electric field, and a longitudinal direction of the opening pattern forms a predetermined angle with respect to a longitudinal direction of the line patterns.

13. The display apparatus of claim 12, wherein a width of each line pattern is substantially equal to or less than about 100 nm, and a width of the opening pattern is in a range of from about 5 μm to about 50 μm.

14. The display apparatus of claim 12, wherein the predetermined angle is in a range of from about 30° to about 60°.

15. The display apparatus of claim 6, wherein the at least one of the first and second electrodes having the first and second line patterns comprises at in least one selected from the group consisting of aluminum (Al), silver (Ag), copper (Cu), molybdenum (Mo), chromium (Cr), tantalum (Ta), titanium (Ti) and an alloy thereof.

16. A display apparatus comprising:
a first substrate;
a gate line formed on the first substrate;
a gate insulating layer formed on the gate line;
a data line intersecting the gate line, and including a source electrode;
a drain electrode facing the source electrode;
a first electrode formed in the pixel area and electrically connected to the drain electrode, the first electrode including a plurality of first line patterns formed thereon to polarize incident light;
a passivation layer covering a channel portion that is formed between the source and drain electrodes, and exposed in the pixel area,
a second substrate facing the first substrate;
a second electrode formed on the second substrate; and
a liquid crystal layer disposed between the first electrode and the second electrode.

17. The display apparatus of claim 16, wherein the second electrode comprises a plurality of second line patterns formed thereon, and a longitudinal direction of the second line patterns is substantially perpendicular to a longitudinal direction of the first line patterns.

18. The display apparatus of claim 16, wherein a distance between adjacent line patterns is substantially equal to or less than about 200 nm.

19. The display apparatus of claim 18, further comprising:
a first alignment layer formed on the first electrode; and
a second alignment layer formed on the second electrode.

20. The display apparatus of claim 16, wherein a width of each line pattern is substantially equal to or less than about 100 nm.

21. The display apparatus of claim 16, wherein the first electrode comprises at least one selected from the group consisting of aluminum (Al), silver (Ag), copper (Cu), molybdenum (Mo), chromium (Cr), tantalum (Ta), titanium (Ti) and an alloy thereof.

22. The display apparatus of claim 16, wherein the first electrode is formed from the same layer as the data line.

23. The display apparatus of claim 16, wherein the first electrode is formed from the same layer as the gate line.

24. The display apparatus of claim 23, wherein the gate insulating layer is exposed in the pixel area.

25. A method for manufacturing a display apparatus, the method comprising:
forming a gate line on a first substrate;
forming a gate insulating layer on the gate line;
forming a data line and a drain electrode, the data line intersecting the gate line and including a source electrode, the drain electrode facing the source electrode;
forming a first electrode electrically connected to the drain electrode, the first electrode including a plurality of line patterns; and
combining a second substrate with the first substrate.

26. The method of claim 25, further comprising forming a second electrode on the second substrate, the second substrate having a plurality of line patterns.

27. The method of claim 26, wherein the first electrode and the second electrode comprise at least one selected from the group consisting of aluminum (Al), silver (Ag), copper (Cu), molybdenum (Mo), chromium (Cr), tantalum (Ta), titanium (Ti) and an alloy thereof.

28. The method of claim 26, wherein forming the first electrode and the second electrode comprises forming an opening pattern to change directions of the line patterns and an electric field.

29. The method of claim 25, wherein forming the first and second electrodes comprises:
coating an opaque conductive material;
coating an organic material on the opaque conductive material; and
compressing the organic material by a mold that has a pattern formed on the mold.

30. The method of claim 25, wherein forming the first and second electrodes comprises:
coating an opaque conductive material;
coating an organic material on the opaque conductive material; and
forming a pattern on the organic material by a laser.
